(19) United States
(12) Patent Application Publication
(10) Pub. No.: US 2014/0363963 A1
(43) Pub. Date: Dec. 11, 2014

(54) METHOD OF MANUFACTURING SEMICONDUCTOR DEVICE

(71) Applicant: Kabushiki Kaisha Toshiba, Minato-ku (JP)

(72) Inventor: Masahiro KIYOTOSHI, Yokkaichi-shi (JP)

(73) Assignee: Kabushiki Kaisha Toshiba, Minato-ku (JP)

(21) Appl. No.: 14/013,351

(22) Filed: Aug. 29, 2013

Related U.S. Application Data
(60) Provisional application No. 61/832,199, filed on Jun. 7, 2013.

(51) Int. Cl. H01L 21/28; H01L 21/033

(52) U.S. Cl. CPC H01L 21/28273; H01L 21/0337
USPC 438/593

(57) ABSTRACT

In one embodiment, a method includes forming workpiece, first and second films on a substrate, processing the second films to form first and second core patterns, forming third and fourth sidewall patterns on side surfaces of the first and second core patterns via first and second sidewall patterns, and removing the first core patterns and first sidewall patterns so that the second core pattern and second to fourth sidewall patterns remain. The method includes processing the first films by transferring the second core pattern and second to fourth sidewall patterns to form third and fourth core patterns, forming fifth and sixth sidewall patterns on side surfaces of the third and fourth core patterns, removing the third core patterns so that the fourth core pattern and fifth and sixth sidewall patterns remain, and processing the workpiece film by transferring the fourth core pattern and fifth and sixth sidewall patterns.

### CROSS REFERENCE TO RELATED APPLICATION

This application is based upon and claims the benefit of priority from the prior U.S. Provisional Patent Application No. 61/832,199 filed on Jun. 7, 2013, the entire contents of which are incorporated herein by reference.

### FIELD

Embodiments described herein relate to a method of manufacturing a semiconductor device.

### BACKGROUND

In recent years, fine patterns of a semiconductor device have been formed by using double sidewall pattern transfer in many cases. In addition, it is studied to introduce quadruple sidewall pattern transfer that repeats the double sidewall pattern transfer twice. However, the quadruple sidewall pattern transfer has problems that the number of steps is increased and requirements for alignment accuracy are more stringent, compared with the double sidewall pattern transfer. In addition, when the quadruple sidewall pattern transfer is introduced to a process of manufacturing a NAND memory, the quadruple sidewall pattern transfer complicates steps of forming ladder portions used to connect device regions and pad portions used to dispose contact plugs on word lines. Accordingly, there is a demand for a method which can form these portions by a simple process.

### BRIEF DESCRIPTION OF THE DRAWINGS

FIGS. 1A to 12D are cross-sectional views, plan views and bird's-eye views illustrating a method of manufacturing a semiconductor device of a first embodiment; and

FIGS. 13A to 22D are cross-sectional views, plan views and bird's-eye views illustrating a method of manufacturing a semiconductor device of a second embodiment.

### DETAILED DESCRIPTION

Embodiments will now be explained with reference to the accompanying drawings.

In one embodiment, a method of manufacturing a semiconductor device includes sequentially forming a workpiece film, a first sacrificial film, a first protective film, a second sacrificial film and a second protective film on a substrate, and processing the second protective film and the second sacrificial film to form first core material patterns having a first width and a second core material pattern having a second width larger than the first width. The method further includes forming first and second sidewall patterns formed of a first sidewall material on side surfaces of the first and second core material patterns, respectively, and forming third and fourth sidewall patterns formed of a second sidewall material on the side surfaces of the first and second core material patterns via the first and second sidewall patterns, respectively. The method further includes removing the first core material patterns and the first sidewall patterns so that the second core material pattern and the second, third and fourth sidewall patterns remain. The method further includes processing the first protective film and the first sacrificial film by transferring the second core material pattern and the second, third and fourth sidewall patterns by etching to form third core material patterns having a third width and a fourth core material pattern having a fourth width larger than the third width, and forming fifth and sixth sidewall patterns formed of a third sidewall material on side surfaces of the third and fourth core material patterns, respectively. The method further includes removing the third core material patterns so that the fourth core material pattern and the fifth and sixth sidewall patterns remain, and processing the workpiece film by transferring the fourth core material pattern and the fifth and sixth sidewall patterns by etching.

### First Embodiment

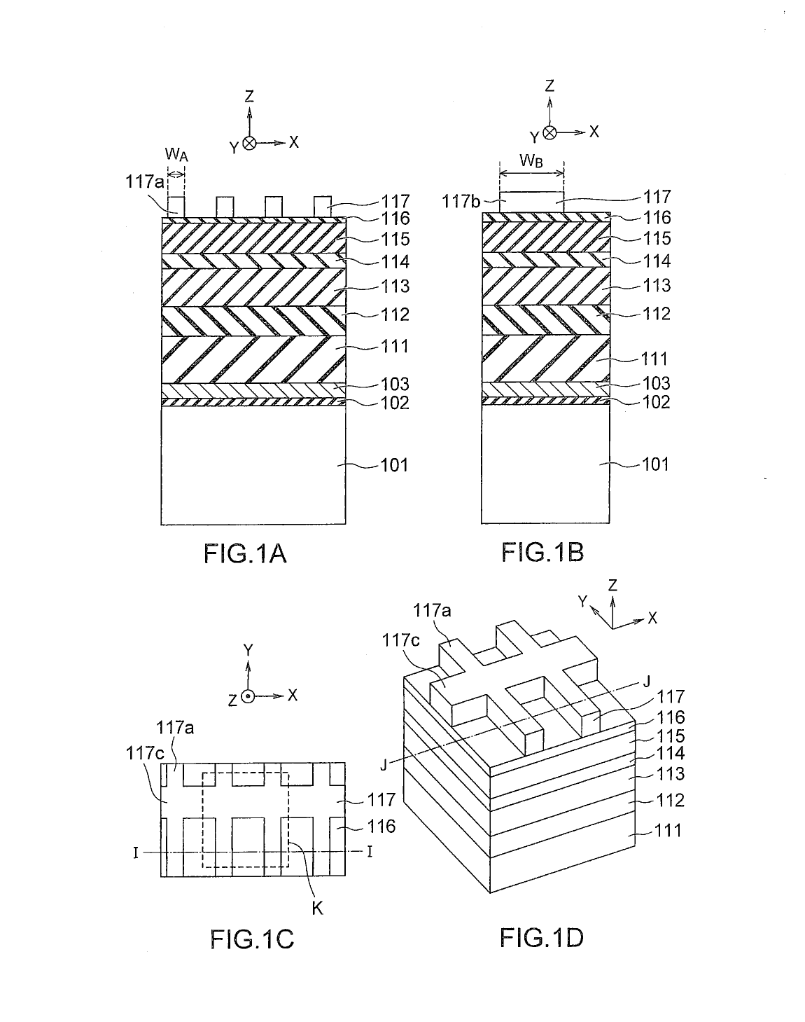

FIGS. 1A to 12D are cross-sectional views, plan views and bird's-eye views illustrating a method of manufacturing a semiconductor device of a first embodiment.

The method of the present embodiment is an example of forming active areas (AAs) and shallow trench isolations (STIs) of a NAND memory by using quadruple sidewall pattern transfer. At this time, ladder portions for connecting the AAs are also formed.

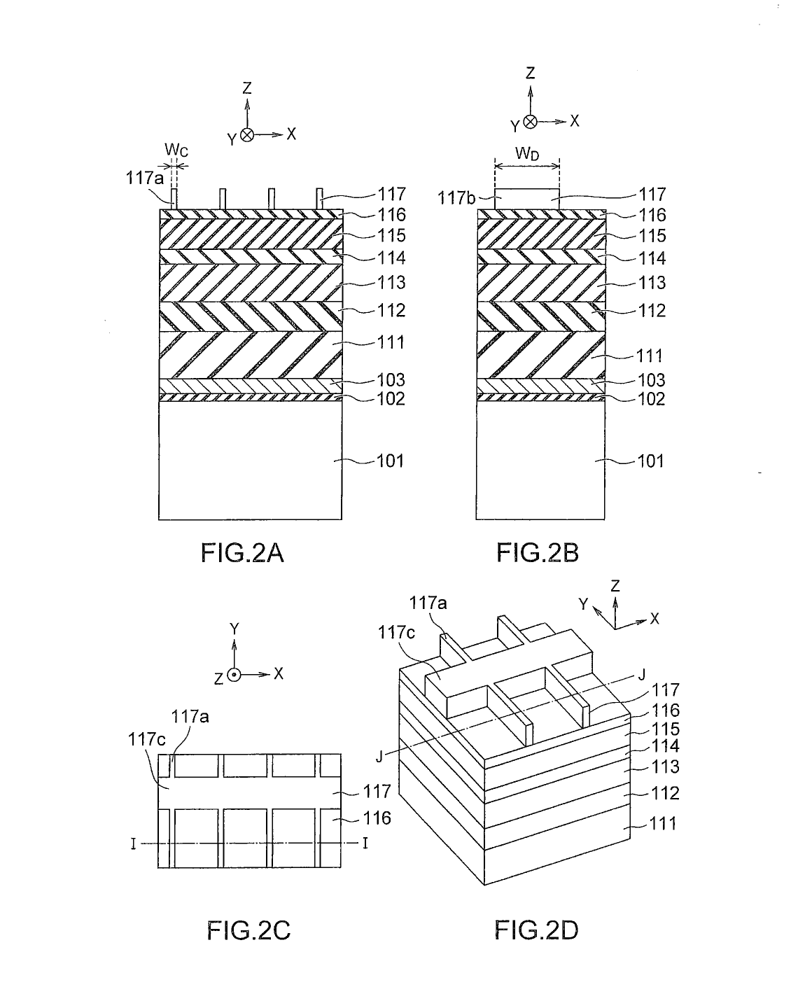

FIGS. 1A and 1B are cross-sectional views which respectively illustrate a memory cell array portion and a peripheral circuit portion of the NAND memory. FIGS. 1C and 1D are respectively a plan view and a bird's-eye view corresponding to FIG. 1A. FIG. 1A represents a cross-sectional view taken on the I-I line in FIG. 1C and the J-J line in FIG. 1D. FIG. 1D corresponds to a region K shown in FIG. 1C. The foregoing is also applied to FIGS. 2A to 12D.

First, as illustrated in FIGS. 1A to 1D, a gate dielectric film 102, a floating gate material 103, a first hard mask layer 111, a second hard mask layer 112, a first sacrificial film 113, a first protective film 114, a second sacrificial film 115, a second protective film 116 and a resist film 117 are sequentially formed on a semiconductor substrate 101 after a well region and a channel region (not shown) are formed in the semiconductor substrate 101 by ion implantation.

The semiconductor substrate 101 is, for example, a silicon substrate. FIGS. 1A to 1D show X and Y directions parallel to a main surface of the semiconductor substrate 101 and perpendicular to each other, and a Z direction perpendicular to the main surface of the semiconductor substrate 101. The present specification treats a +Z direction as an upward direction and a −Z direction as a downward direction. For example, the positional relationship between the semiconductor substrate 101 and the floating gate material 103 is described that the semiconductor substrate 101 is located under the floating gate material 103.

The gate dielectric film 102 and the floating gate material 103 are, for example, a silicon oxide film and a polysilicon layer, respectively. The gate dielectric film 102 and the floating gate material 103 are an example of a workpiece film. The thickness of the gate dielectric film 102 is, for example, 6 nm, and the thickness of the floating gate material 103 is, for example, 50 nm.

The first hard mask layer 111 and the second hard mask layer 112 are, for example, a silicon oxide film and an amorphous silicon layer, respectively, and are formed by low pressure chemical vapor deposition (LPCVD). The thickness of the first hard mask layer 111 is, for example, 150 nm, and the thickness of the second hard mask layer 112 is, for example, 100 nm.

The first sacrificial film 113 is, for example, a carbon film, and is formed by plasma CVD. The carbon film is an example of a carbon-containing film. The first protective film 114 is used to protect the first sacrificial film 113. The first protective film 114 is, for example, a silicon oxynitride (SION) film, and is formed by plasma CVD. The thickness of the first sacrificial film 113 is, for example, 120 nm, and the thickness of the first protective film 114 is, for example, 50 nm.

The second sacrificial film 115 is, for example, a spin-on-carbon (SOC) film, and is formed by coating. The SOC film is an example of a carbon-containing film. The second protective film 116 is used to protect the second sacrificial film 115. The second protective film 116 is, for example, a silicon oxynitride film, and is formed by plasma CVD. The thickness of the second sacrificial film 115 is, for example, 100 nm, and the thickness of the second protective film 116 is, for example, 30 nm.

Next, as illustrated in FIGS. 1A to 1D, the resist film 117 is patterned by lithography to form first resist patterns 117a having a width W_{A} and a second resist pattern 117b having a width W_{B} larger than the width W_{A}.

The first resist patterns 117a are used to form the AAs and the STIs of the memory cell array portion, whereas the second resist pattern 117b is used to form the AAs and the STIs of the peripheral circuit portion. The width W_{A} is set to, for example, 3F (“F” denotes a feature size which is the minimum dimension in the generation of the semiconductor device of the present embodiment). The value of “F” is, for example, 16 nm.

In the above lithography, there is further formed a ladder portion 117c for connecting the first resist patterns 117a to one another. In FIGS. 1A to 1D, each first resist pattern 117a extends in the Y direction and the ladder portion 117c extends in the X direction.

Next, as illustrated in FIGS. 2A to 2D, the first and second resist patterns 117a and 117b are slimmed by ashing or the like so that the first resist patterns 117a have a desired width. As a result, the width of the first resist patterns 117a is decreased to W_{C} (<W_{A}), and the width of the second resist pattern 117b is decreased to W_{D} (<W_{B}). The width W_{C} is set to, for example, a feature size “F”.

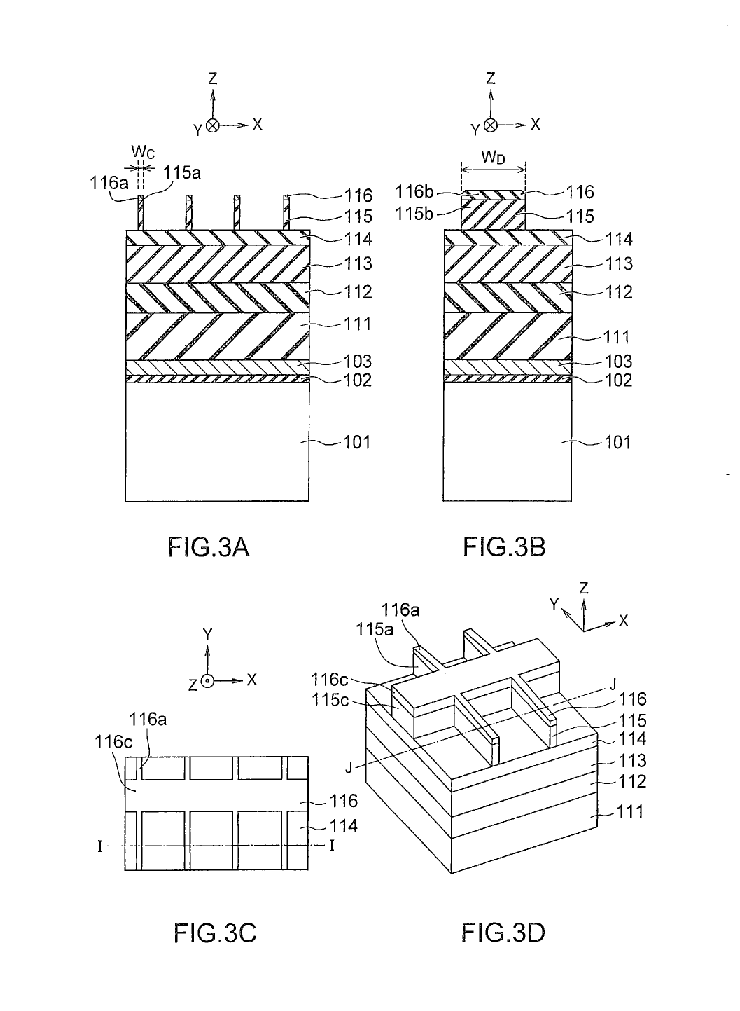

Next, as illustrated in FIGS. 3A to 3D, the second protective film 116 and the second sacrificial film 115 are processed by reactive ion etching (RIE) using the resist film 117 as a mask. As a result, the second sacrificial film 115 and the second protective film 116 are processed into first core material patterns 115a, 116a having a first width W_{C} and a second core material pattern 115b, 116b having a second width W_{D} larger than the first width W_{C}. In addition, there are formed a first ladder portion 115c, 116c for connecting the first core material patterns 115a, 116a to one another.

At this time, the etching rates of the second protective film 116 and the second sacrificial film 115 are affected by a loading effect. The loading effect causes the etching rate of a thin pattern to become faster, whereas it causes the etching rate of a thick pattern to become slower. The reason for this is that the thin pattern is more largely affected by etching from side surfaces, compared with the thick pattern. The influence of the loading effect generally becomes more significant as a pattern becomes finer.

FIGS. 3A to 3D illustrate a condition that the thickness of the second protective film 116 in the first core material patterns 115a, 116a becomes smaller than the thickness of the second protective film 116 in the second core material pattern 115b, 116b and the first ladder portion 115c, 116c due to the loading effect. Although the second protective film 116 in the first core material patterns 115a, 116a is thinned here, it may be removed by the loading effect.

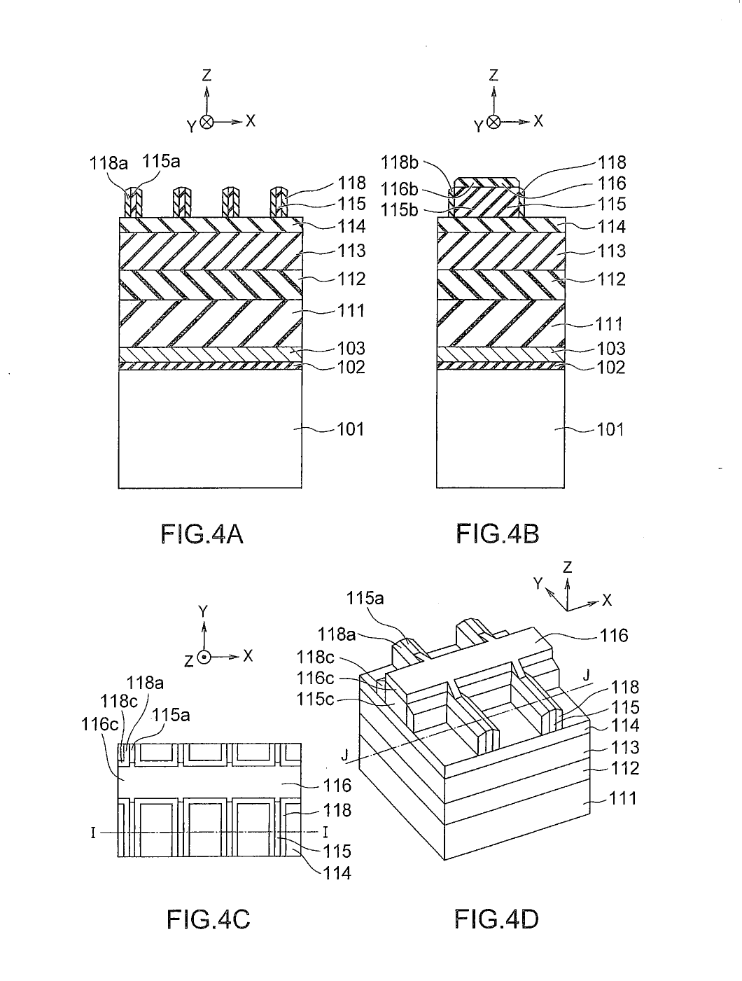

Next, as illustrated in FIGS. 4A to 4D, a first sidewall material 118 is formed on the entire surface of the semiconductor substrate 101 by CVD or atomic layer deposition (ALD). Thereafter, the first sidewall material 118 is subjected to spacer processing by RIE.

As a result, first sidewall patterns 118a, second sidewall patterns 118b, and first ladder sidewall patterns 118c are formed on side surfaces of the first core material patterns 115a, 116a, the second core material pattern 115b, 116b, and the first ladder portion 115c, 116c, respectively. At this time, the second protective film 116 in the first core material patterns 115a, 116a is either thinned or removed.

The first sidewall material 118 is, for example, a carbon film. The thickness of the first sidewall material 118 is set to, for example, the feature size “F”.

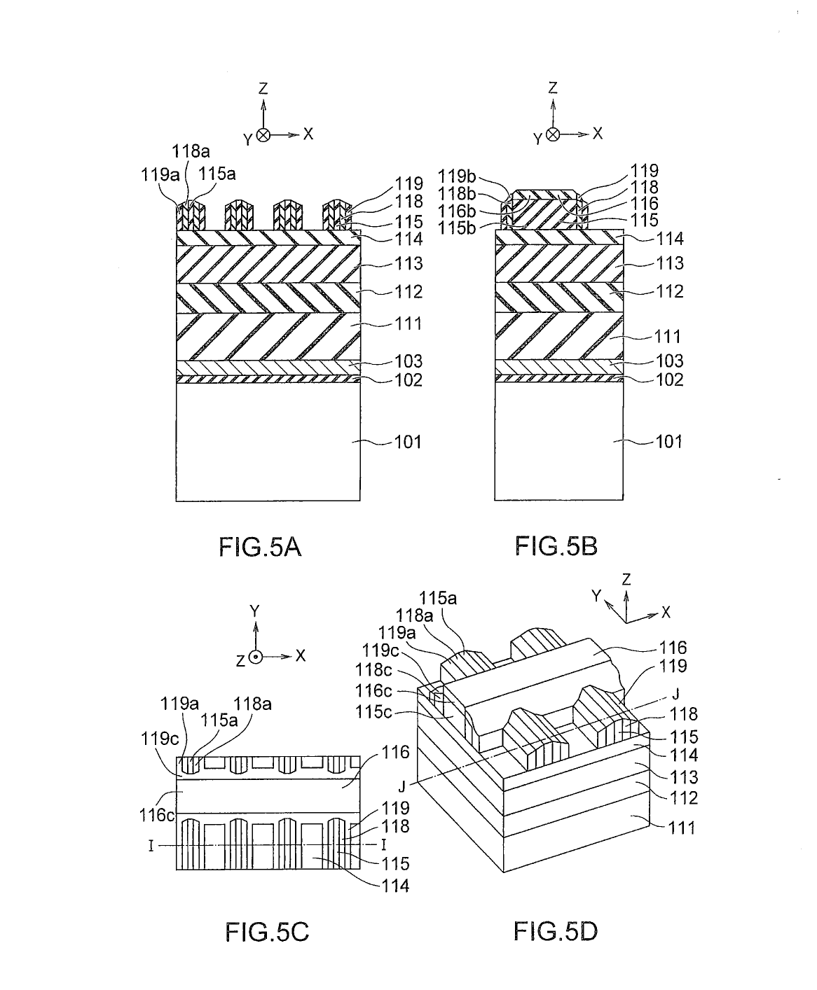

Next, as illustrated in FIGS. 5A to 5D, a second sidewall material 119 is formed on the entire surface of the semiconductor substrate 101 by ALD. Thereafter, the second sidewall material 119 is subjected to spacer processing by RIE.

As a result, third sidewall patterns 119a, fourth sidewall patterns 119b, and second ladder sidewall patterns 119c are formed on the side surfaces of the first core material patterns 115a, 116a, the second core material patterns 115b, 116b, and the first ladder portions 115c, 116c via the first sidewall patterns 118a, the second sidewall patterns 118b, and the first ladder sidewall patterns 118c, respectively. The second protective film 116 in the first core material patterns 115a, 116a is completely removed by the end of this process.

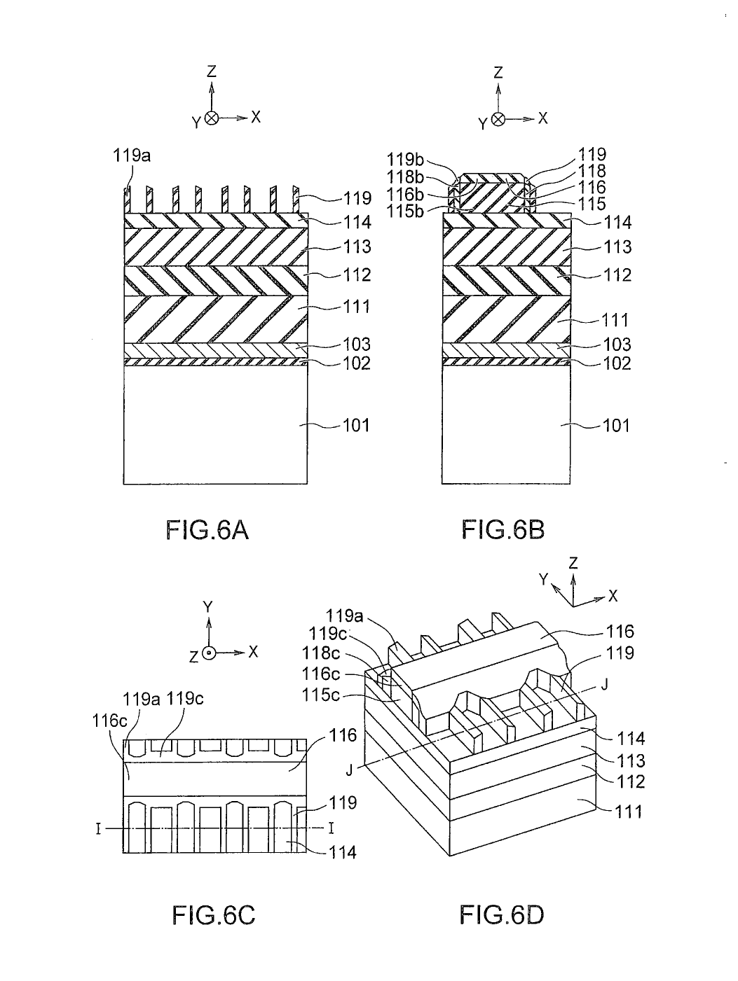

The second sidewall material 119 is formed of a material different from those of the second sacrificial film 115 and the first sidewall material 118 so as to selectively leave the second sidewall material 119 in the following process of FIGS. 6A to 6D. The second sidewall material 119 is, for example, a silicon oxide film. The thickness of the second sidewall material 119 is set to, for example, the feature size “F”.

Next, as illustrated in FIGS. 6A to 6D, the second sacrificial film 115 and the first sidewall material 118 are selectively removed by ashing or RIE using an oxygen (O₂) gas.

At this time, the second sacrificial film 115 in the first core material patterns 115a is removed since it is not covered with the second protective film 116. On the other hand, the second sacrificial film 115 in the second core material pattern 115b, 116b and the first ladder portion 115c, 116c remains since it is covered with the second protective film 116. Similarly, the first sidewall patterns 118a are removed since they are not covered with the third sidewall patterns 119a. On the other hand, the second sidewall patterns 118b and the first ladder sidewall patterns 118c remain since they are respectively covered with the fourth sidewall patterns 119b and the second ladder sidewall patterns 119c.

As a result, the first core material patterns 115a and the first sidewall patterns 118a are removed, and the second core material pattern 115b, 116b, the second sidewall patterns 118b, the third sidewall patterns 119a, and the fourth sidewall patterns 119b remain in the process of FIGS. 6A to 6D. In addition, the first ladder portion 115c, 116c, the first ladder sidewall patterns 118c, and the second ladder sidewall patterns 119c also remain.

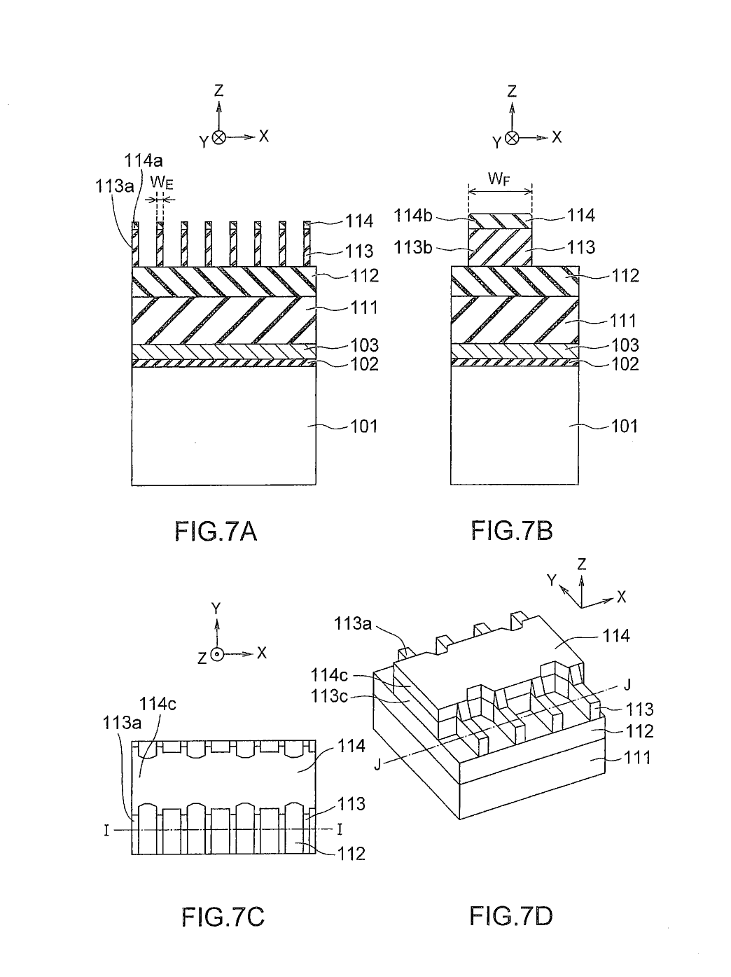

Next, as illustrated in FIGS. 7A to 7D, these remaining patterns are transferred to the first protective film 114 and the first sacrificial film 113 by etching using these patterns as a mask. As a result, the first sacrificial film 113 and the first protective film 114 are processed into third core material patterns 113a, 114a having a third width W_{E} and a fourth core material pattern 113b, 114b having a fourth width W_{F} larger than the third width W_{E}. In addition, there are formed a second ladder portion 113c, 114c for connecting the third core material patterns 113a, 114a to one another. The third width W_{E} is, for example, the feature size “F”.

At this time, the etching rates of the first protective film 114 and the first sacrificial film 113 are affected by the loading effect.

FIGS. 7A to 7D illustrate a condition that the thickness of the first protective film 114 in the third core material patterns 113a, 114a becomes smaller than the thickness of the first protective film 114 in the fourth core material pattern 113b, 114b and the second ladder portion 113c, 114c due to the loading effect. Although the first protective film 114 in the third core material patterns 113a, 114a is thinned here, it may be removed by the loading effect.

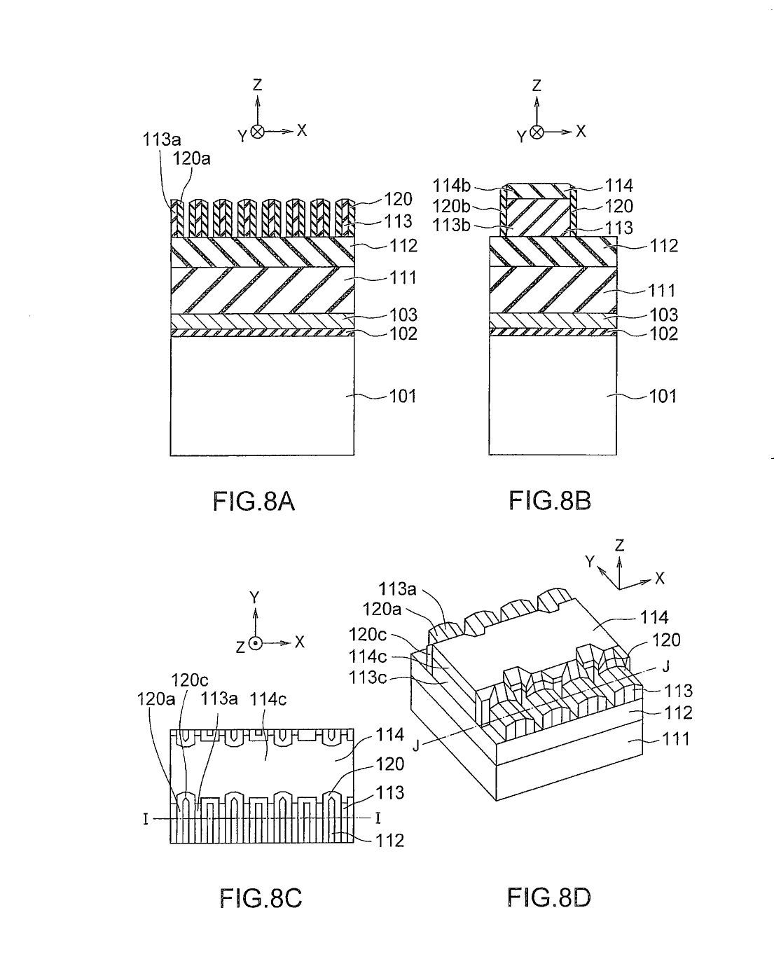

Next, as illustrated in FIGS. 8A to 8D, a third sidewall material 120 is formed on the entire surface of semiconductor substrate 101 by ALD. Thereafter, the third sidewall material 120 is subjected to spacer processing by RIE.

As a result, fifth sidewall patterns 120a, sixth sidewall patterns 120b, and third ladder sidewall patterns 120c are formed on side surfaces of the third core material patterns 113a, 114a, the fourth core material pattern 113b, 114b, and the second ladder portion 113c, 114c, respectively. The first protective film 114 in the third core material patterns 113a, 114a is completely removed by the end of this process.

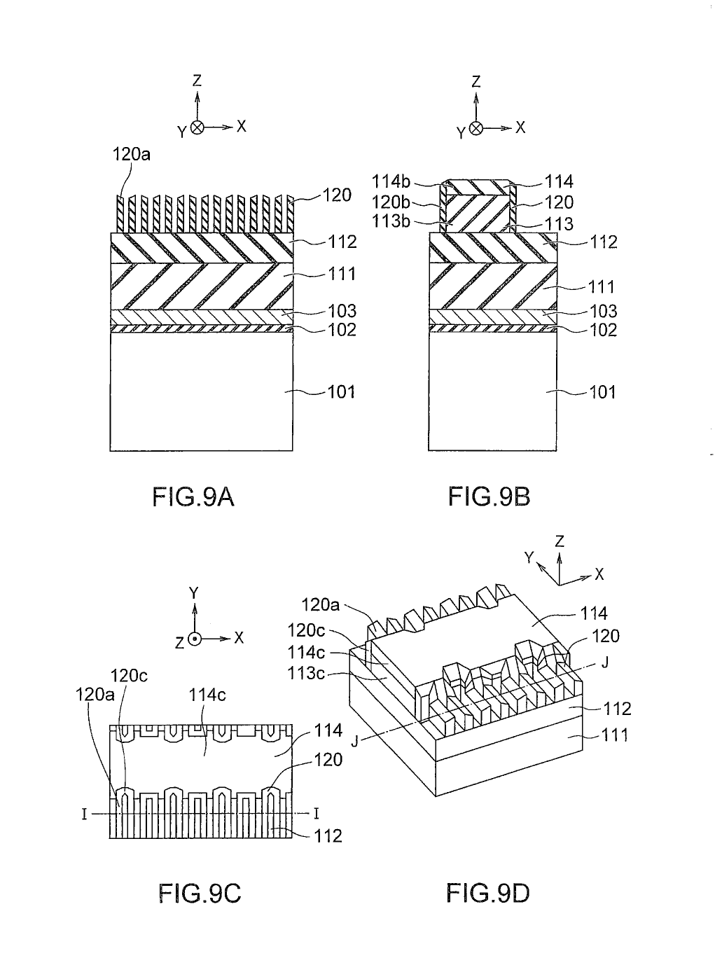

The third sidewall material 120 is formed of a material different from that of the first sacrificial film 113 so as to selectively leave the third sidewall material 120 in the following process of FIGS. 9A to 9D. The third sidewall material 120 is, for example, a silicon oxide film. The thickness of the third sidewall material 120 is set to, for example, the feature size “F”.

Next, as illustrated in FIGS. 9A to 9D, the third sacrificial film 113 is selectively removed by ashing or RIE using an oxygen gas.

At this time, the first sacrificial film 113 in the third core material patterns 113a is removed since it is not covered with the first protective film 114. On the other hand, the first sacrificial film 113 in the fourth core material pattern 113b, 114b and the second ladder portion 113c, 114c remain since it is covered with the first protective film 114.

As a result, the third core material patterns 113a are removed, and the fourth core material pattern 113b, 114b, the fifth sidewall patterns 120a, and the sixth sidewall patterns 120b remain in the process of FIGS. 9A to 9D. In addition, the second ladder portion 113c, 114c and the third ladder sidewall patterns 120c also remain.

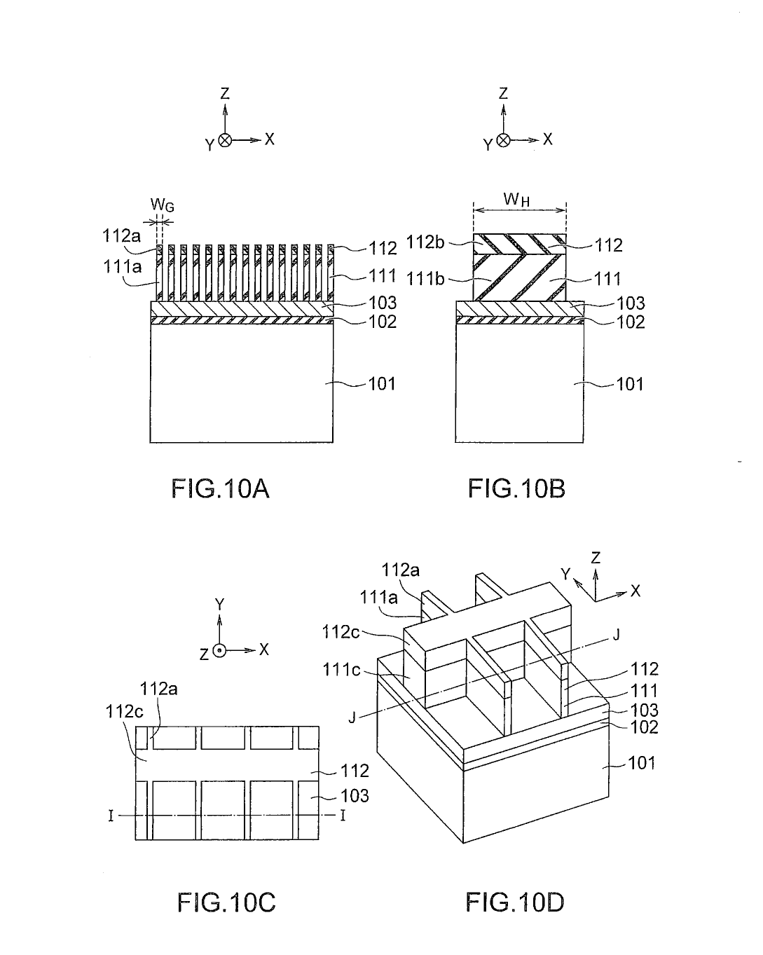

Next, as illustrated in FIGS. 10A to 10D, these remaining patterns are transferred to the second hard mask layer 112 and further to the first hard mask layer 111 by etching using these patterns as a mask.

As a result, the first and second hard mask layers 111 and 112 are processed into first mask patterns 111a, 112a having a fifth width W_{G} and a second mask pattern 111b, 112b having a sixth width W_{H} larger than the fifth width W_{G}. In addition, there are formed a ladder portion 111c, 112c for connecting the first mask patterns 111a, 112a to one another. The fifth width W_{G} is, for example, the feature size “F”.

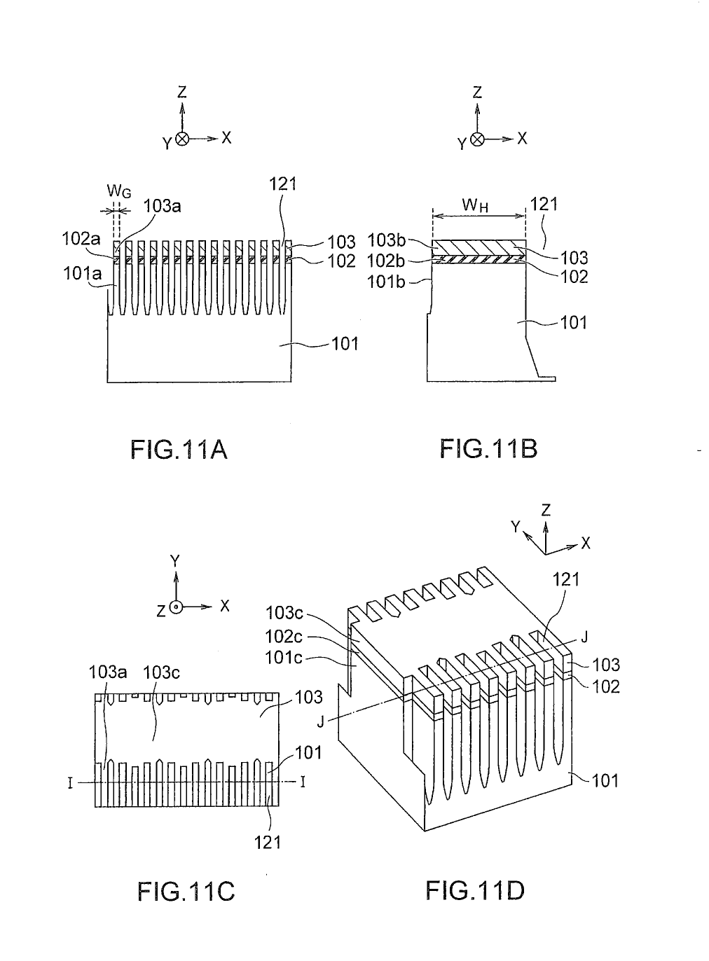

Next, as illustrated in FIGS. 11A to 11D, these patterns are transferred to the floating gate material 103, the gate dielectric film 102 and the semiconductor substrate 101 by etching using these patterns as a mask.

As a result, isolation trenches 121 dividing the floating gate material 103 and the gate dielectric film 102 are formed on a surface of the semiconductor substrate 101. In addition, there are also formed first device regions (AA) 101a having the fifth width W_{G}, a second device region 101b having the sixth width W_{H} larger than the fifth width W_{G}, and a ladder portion 101c for connecting the first device regions 101a to one another. The depth from the upper surface of the semiconductor substrate 101 to the bottom surfaces of the isolation trenches 121 is set to, for example, 180 nm.

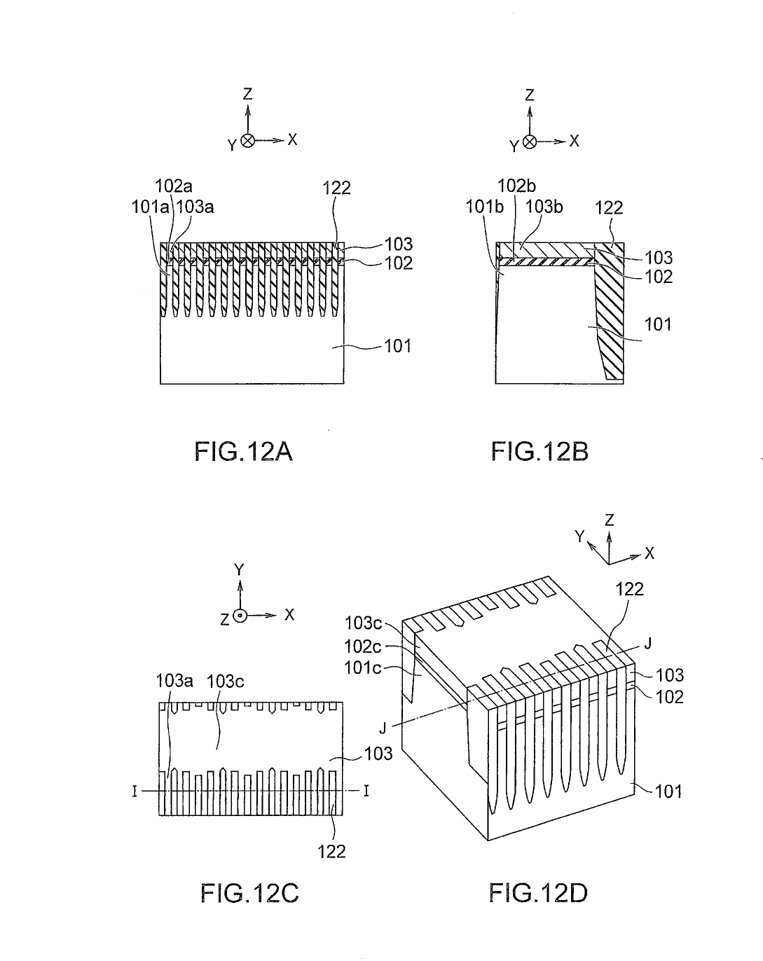

Next, as illustrated in FIGS. 12A to 12D, an insulating layer is embedded in the isolation trenches 121. Then, this insulating layer is planarized by chemical mechanical polishing (CMP). As a result, isolation insulators (STIs) 122 are formed on the surface of the semiconductor substrate 101.

### Effects of First Embodiment

Hereinafter, a description will be given of effects of the first embodiment.

The method of the present embodiment allows the quadruple sidewall pattern transfer to be performed by only one lithography process shown in FIGS. 1A to 1D. According to the present embodiment, both a thin pattern for the AAs in the memory cell array portion and a thick pattern for the AAs in the peripheral circuit portion can be formed in the same lithography process.

Conventional quadruple sidewall pattern transfer requires a lithography process of forming the thin pattern and a lithography process of forming the thick pattern. The reason for this is that if these patterns are processed at the same time, a portion of the thick pattern which needs to be left is also etched when the thin pattern is processed by etching.

On the other hand, in the method of the present embodiment, the width W_{C} of the first core material patterns 115a, 116a is previously set to a small value (for example, W_{C}=F). Consequently, the thickness of the second protective film 116 in the first core material patterns 115a, 116a becomes significantly smaller than the thickness of the second protective film 116 in the second core material pattern 115b, 116b due to the loading effect as the process of FIGS. 3A to 3D advances.

Accordingly, the second protective film 116 in the first core material patterns 115a, 116a can be removed by the end of the process of FIGS. 5A to 5D, while the second protective film 116 in the second core material pattern 115b, 116b remains. It is therefore possible to remove the first core material patterns 115a in the process of FIGS. 6A to 6D, while the second core material pattern 115b, 116b remains. In this way, according to the present embodiment, the patterns shown in FIGS. 6A to 6D can be formed by one lithography process.

When the width W_{C} of the first core material patterns 115a, 116a is set to a small value, it is not possible to secure a core material width required for the quadruple sidewall pattern transfer. Therefore, the first sidewall patterns 118a are formed on the side surfaces of the first core material patterns 115a, 116a before forming the third sidewall patterns 119a in the present embodiment. Consequently, according to the present embodiment, a substantial core material width can be increased to the sum of the widths of a first core material pattern 115a, 116a and first sidewall patterns 119a to secure the required core material width.

In the present embodiment, the width W_{E} of the third core material patterns 113a, 114a is also set to a small value (for example, W_{E}=F). Consequently, the third core material patterns 113a can be removed in the process of FIGS. 9A to 9D, while the fourth core material pattern 113b, 114b remains. In this way, according to the present embodiment, the patterns shown in FIGS. 9A to 9D can be formed by one lithography process.

For the reason described above, the present embodiment also allows a ladder portion for connecting the AAs to one another to be formed in the same lithography process, in addition to the thin pattern for the AAs in the memory cell array portion and the thick pattern for the AAs in the peripheral circuit portion. According to the ladder portion of the present embodiment, it is possible to prevent patterns from collapse and to decrease the number of source contacts.

The method of the present embodiment uses films which contain carbon (carbon-containing films) as the first sacrificial film 113, the second sacrificial film 115 and the first sidewall material 118. The carbon-containing films have advantages that higher etching selectivity thereof for RIE can be easily obtained with respect to a silicon oxide film and a silicon nitride film and that the carbon-containing films can be removed by ashing. Accordingly, the first sacrificial film 113, the second sacrificial film 115 and the first sidewall material 118 can be removed without applying wet etching when the carbon-containing films are used for these films. There is therefore no need for drying treatment after wet etching in this case. In addition, it is possible to prevent pattern leaning due to drying treatment in this case.

The material of the second sacrificial film 115 and the first sidewall material 118 (hereinafter referred to as Material 1), the material of the second sidewall material 119 (hereinafter referred to as Material 2), and the method of removing the second sacrificial film 115 and the first sidewall material 118 (hereinafter referred to as Method 1) allow for use in a variety of combinations.

For example, Material 1, Material 2, and Method 1 may respectively be a silicon oxide film, a silicon nitride film, and wet etching using buffered hydrofluoric acid in a case where wet etching is used.

Alternatively, Material 1, Material 2, and Method 1 may respectively be a silicon nitride film, a silicon oxide film, and wet etching using hot phosphoric acid.

Furthermore, Material 1, Material 2, and Method 1 may respectively be a silicon oxide film, a titanium nitride film, and wet etching using buffered hydrofluoric acid.

Material 1, Material 2, and Method 1 may also be applied as a combination of the material of the first sacrificial film 113, the material of the third sidewall material 120, and the method of removing the first sacrificial film 113.

As described above, according to the present embodiment, the quadruple sidewall pattern transfer can be performed with a reduced number of steps because both a thin pattern and a thick pattern can be formed by the same process.

In addition, according to the present embodiment, it is possible to form fine patterns having a width which is approximately a feature size, by the quadruple sidewall pattern transfer with a reduced number of steps. Although the present embodiment has presented an example in which fine patterns having a width “F” are formed in a case where F=16 nm, it is possible according to the present embodiment to form fine patterns having a width of 20 nm or smaller by using the quadruple sidewall pattern transfer.

### Second Embodiment

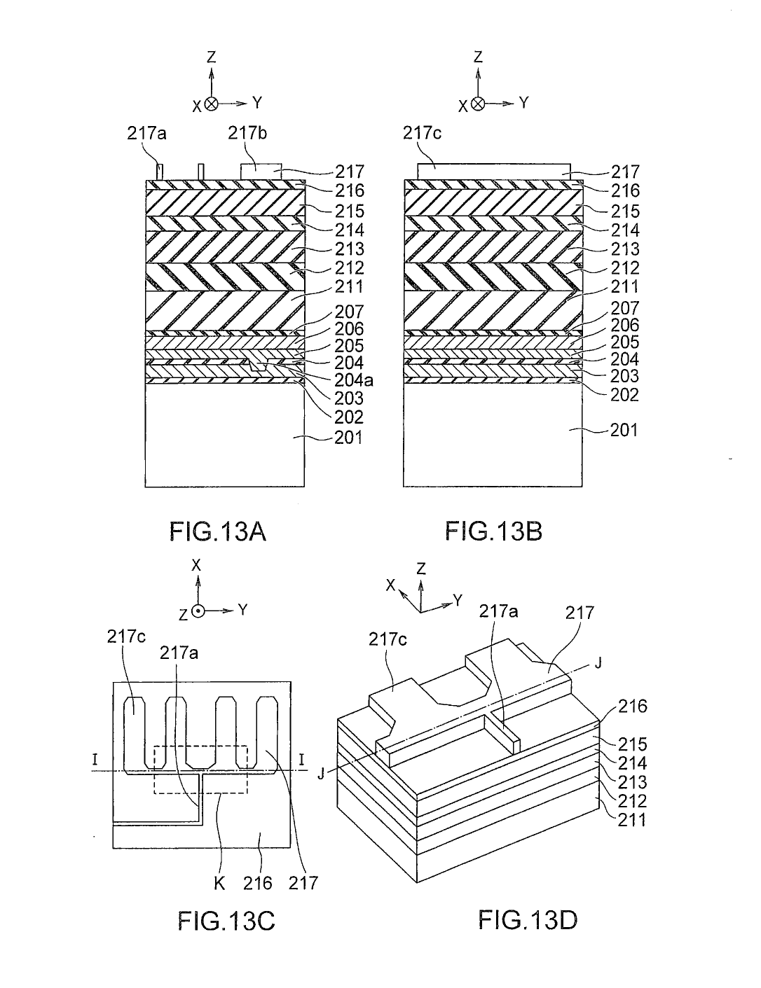

FIGS. 13A to 22D are cross-sectional views, plan views and bird's-eye views illustrating a method of manufacturing a semiconductor device of a second embodiment.

The method of the present embodiment is an example of forming word lines and select lines of a NAND memory by using quadruple sidewall pattern transfer. In other words, the present embodiment shows a case of forming gate structures of cell transistors and select transistors of the NAND memory. At this time, pad portions (hookup portion) connected to the word lines are also formed. A process of manufacturing the select transistors in the present embodiment is also applicable to peripheral transistors.

The following description of the second embodiment will omit to describe matters common to the first embodiment.

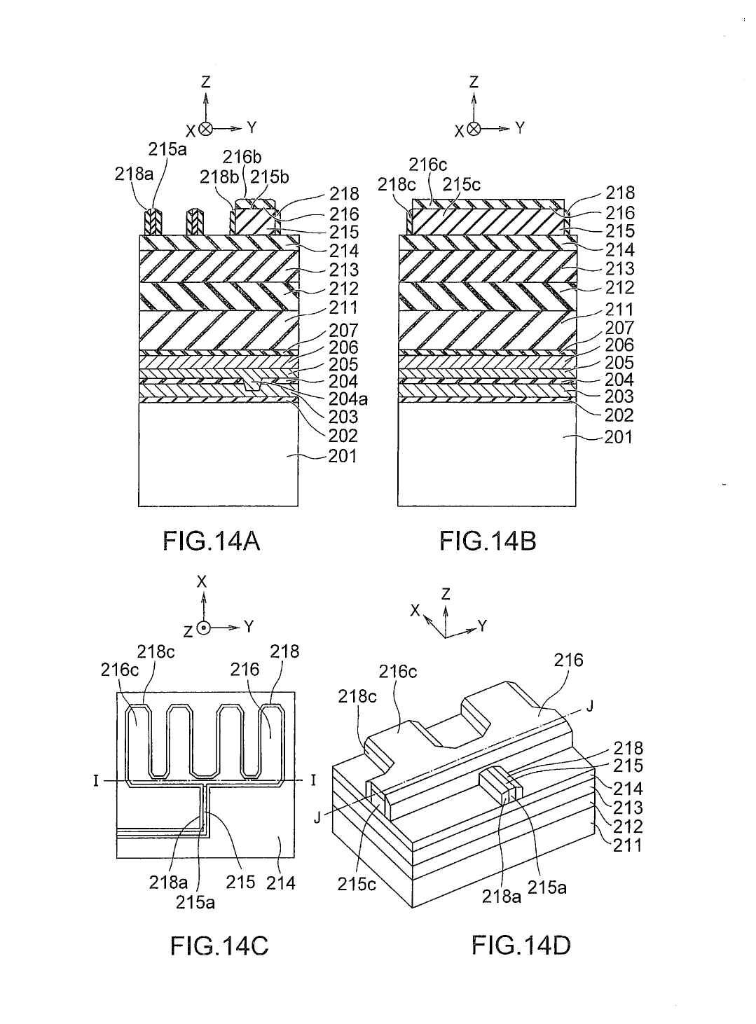

FIGS. 13A and 13B are cross-sectional views which respectively illustrate a memory cell array portion and the hookup portion of the NAND memory. FIGS. 13C and 13D are respectively a plan view and a bird's-eye view corresponding to FIG. 13B. FIG. 13B illustrates a cross-sectional view taken on the I-I line in FIG. 13C and the J-J line in FIG. 13D. FIG. 13D corresponds to a region K shown in FIG. 13C. The foregoing is also applied to FIGS. 14A to 22D.

First, as illustrated in FIGS. 13A to 13D, a gate dielectric film 202, a floating gate material 203, an intergate dielectric film 204, a first control gate material 205, a second control gate material 206, a cap layer 207, a first hard mask layer 211, a second hard mask layer 212, a first sacrificial film 213, a first protective film 214, a second sacrificial film 215, a second protective film 216 and a resist film 217 are sequentially formed on a semiconductor substrate 201 after a well region and a channel region (not shown) are formed in a semiconductor substrate 201 by ion implantation.

In the present embodiment, AAs and STIs are formed on the semiconductor substrate 201 between a step of forming the floating gate material 203 and a step of forming the intergate dielectric film 204.

The intergate dielectric film 204, the first control gate material 205, the second control gate material 206, and the cap layer 207 are, for example, a silicon oxide film, a polysilicon layer, a tungsten/tungsten nitride stack film, and a silicon nitride film, respectively. The gate dielectric film 202, the floating gate material 203, the intergate dielectric film 204, the first control gate material 205, the second control gate material 206 and the cap layer 207 are an example of a workpiece film. The thicknesses of the intergate dielectric film 204, the first control gate material 205, the second control gate material 206 and the cap layer 207 are, for example, 9 nm, 20 nm, 50 nm and 20 nm, respectively.

In the present embodiment, an opening 204a penetrating the intergate dielectric film 204 is formed for the gate electrode of a select transistor between a step of forming the first control gate material 205 and a step of forming the second control gate material 206.

For the materials, thicknesses, and formation methods of other layers shown in FIGS. 13A to 13D, the same materials, thicknesses, and formation methods as those of the first embodiment may be adopted. However, similarly to the first sacrificial film 213, the second sacrificial film 215 of the present embodiment is, for example, a carbon film to be formed by LPCVD.

Next, as illustrated in FIGS. 13A to 13D, the resist film 217 is patterned by lithography to form first resist patterns 217a and a second resist pattern 217b having a width larger than that of the first resist patterns 217a. In this lithography, there is further formed a plurality of pad portions 217c connected to a first resist pattern 217a. In FIG. 13A, the first and second resist patterns 217a and 217b extend in the X direction.

Next, as illustrated in FIGS. 13A to 13D, the first and second resist patterns 217a and 217b are slimmed by ashing or the like so that the first resist patterns 217a have a desired width. As a result, the first and second resist patterns 217a and 217b are decreased in width.

The first resist patterns 217a are used to form cell transistors, whereas the second resist pattern 217b is used to form a select transistor. For example, the width of the first resist patterns 217a is set to 3F before slimming, and set to “F” after slimming (“F” denotes a feature size). The value of “F” is, for example, 13 nm.

Next, as illustrated in FIGS. 14A to 14D, the second protective film 216 and the second sacrificial film 215 are processed by RIE using the resist film 217 as a mask. As a result, the second sacrificial film 215 and the second protective film 216 are processed into first core material patterns 215a, 216a having a first width and a second core material pattern 215b, 216b having a second width larger than the first width. There is further formed a plurality of first pad portions 215c, 216c connected to a first core material pattern 215a, 216a.

At this time, the etching rates of the second protective film 216 and the second sacrificial film 215 are affected by the loading effect, similarly to the first embodiment.

Next, as illustrated in FIGS. 14A to 14D, a first sidewall material 218 is formed on the entire surface of the semiconductor substrate 201 by CVD or ALD. Thereafter, the first sidewall material 218 is subjected to spacer processing by RIE.

As a result, first sidewall patterns 218a, second sidewall patterns 218b, and a first pad sidewall pattern 218c are formed on side surfaces of the first core material patterns 215a, 216a, the second core material patterns 215b, 216b, and the first pad portions 215c, 216c, respectively. The thickness of the first sidewall material 218 is set to, for example, the feature size “F”.

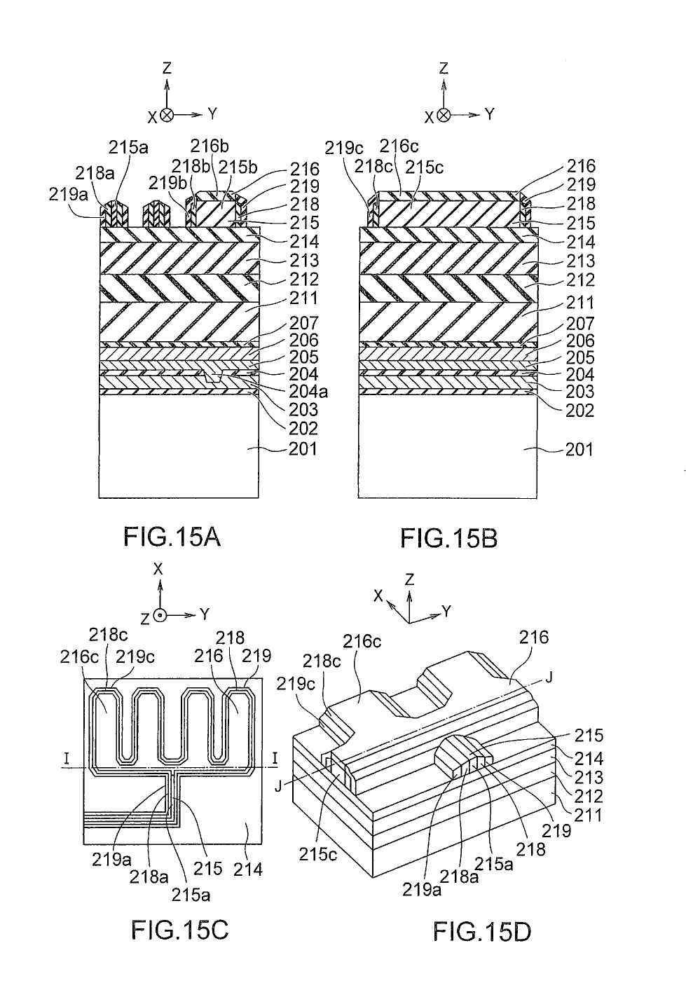

Next, as illustrated in FIGS. 15A to 15D, a second sidewall material 219 is formed on the entire surface of the semiconductor substrate 201 by ALD. Thereafter, the second sidewall material 219 is subjected to spacer processing by RIE.

As a result, third sidewall patterns 219a, fourth sidewall patterns 219b, and a second pad sidewall pattern 219c are formed on the side surfaces of the first core material patterns 215a, 216a, the second core material patterns 215b, 216b, and the first pad portions 215c, 216c via the first sidewall patterns 218a, the second sidewall patterns 218b, and the first pad sidewall pattern 218c, respectively. The second protective film 216 in the first core material patterns 215a, 216a is completely removed by the end of this process. The thickness of the second sidewall material 219 is set to, for example, the feature size “F”.

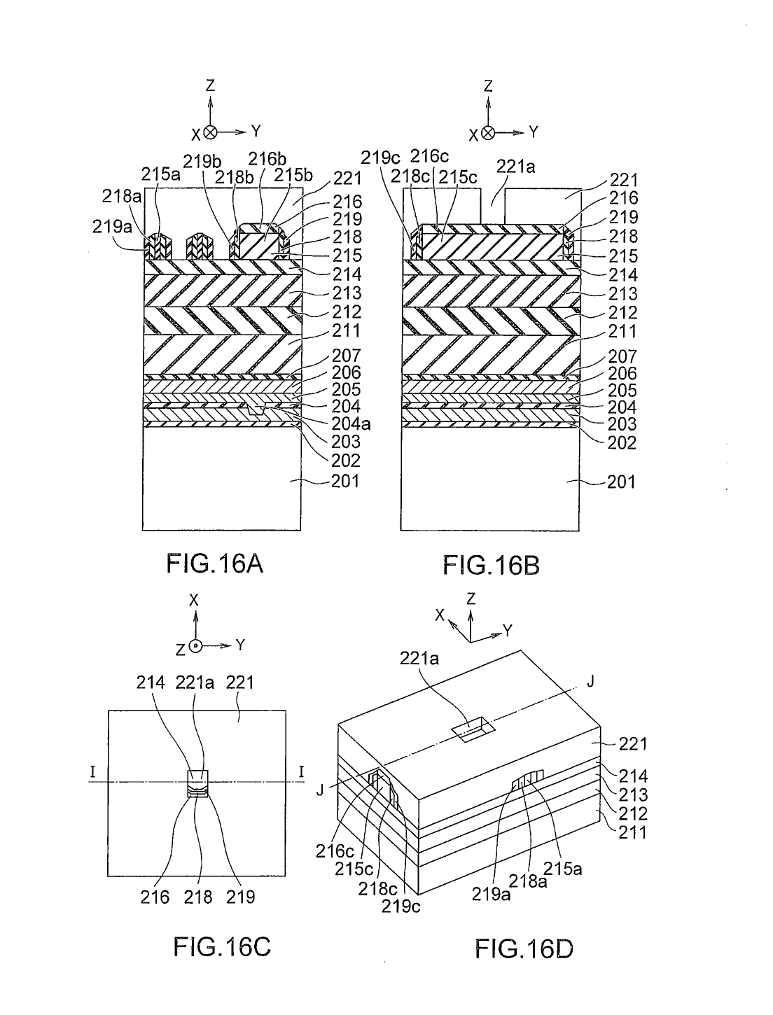

Next, as illustrated in FIGS. 16A to 16D, a resist film 221 is formed on the entire surface of the semiconductor substrate 201. One resist opening 221a is then formed on the first pad portions 215c, 216c, the first pad sidewall pattern 218c and the second pad sidewall pattern 219c by lithography.

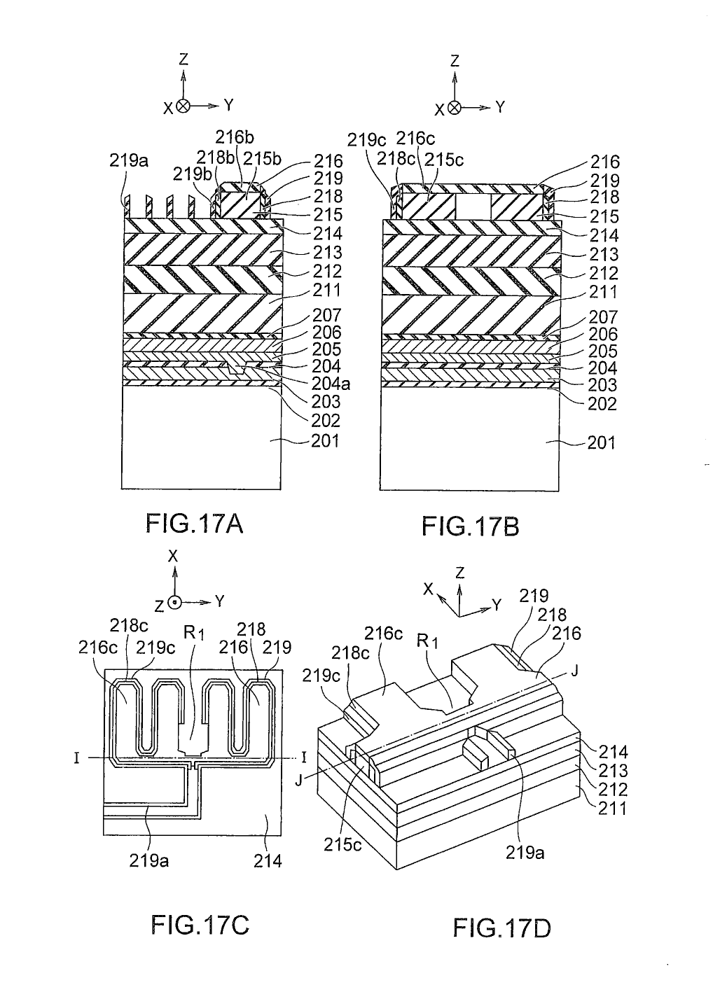

Next, the first pad portions 215c, 216c, the first pad sidewall pattern 218c, and the second pad sidewall pattern 219c in the resist opening 221a are etched by wet etching and RIE. As a result, the first and second pad sidewall patterns 218c and 219c are loop-cut to be divided into two parts (see FIGS. 17A to 17D).

Next, as illustrated in FIGS. 17A to 17D, the resist film 221, the second sacrificial film 215, and the first sidewall material 218 are selectively removed by isotropic etching such as ashing.

At this time, the second sacrificial film 215 in the first core material patterns 215a is removed since it is not covered with the second protective film 216. On the other hand, the second sacrificial film 215 in the second core material pattern 215b, 216b and the first pad portions 215c, 216c remain since it is covered with the second protective film 216.

Similarly, the first sidewall patterns 218a are removed since they are not covered with the third sidewall patterns 219a. On the other hand, the second sidewall patterns 218b and the first pad sidewall pattern 218c remain since they are covered with the fourth sidewall patterns 219b and the second pad sidewall pattern 219c, respectively.

As a result, the first core material patterns 215a and the first sidewall patterns 218a are removed, whereas the second core material pattern 215b, 216b, the second sidewall patterns 218b, the third sidewall patterns 219a, and the fourth sidewall patterns 219b remain in the process of FIGS. 17A to 17D. In addition, the first pad portions 215c, 216c, the first pad sidewall pattern 218c, and the second pad sidewall pattern 219c also remain.

The second sacrificial film 215 in the first pad portions 215c, 216c are etched in the vicinity of a region R₁ by the action of the isotropic etching. As a result, the second sacrificial film 215 in the first pad portions 215c, 216c is divided in the vicinity of the region R₁. This isotropic etching is continued until the division of the second sacrificial film 215 in the first pad portions 215c, 216c is completed.

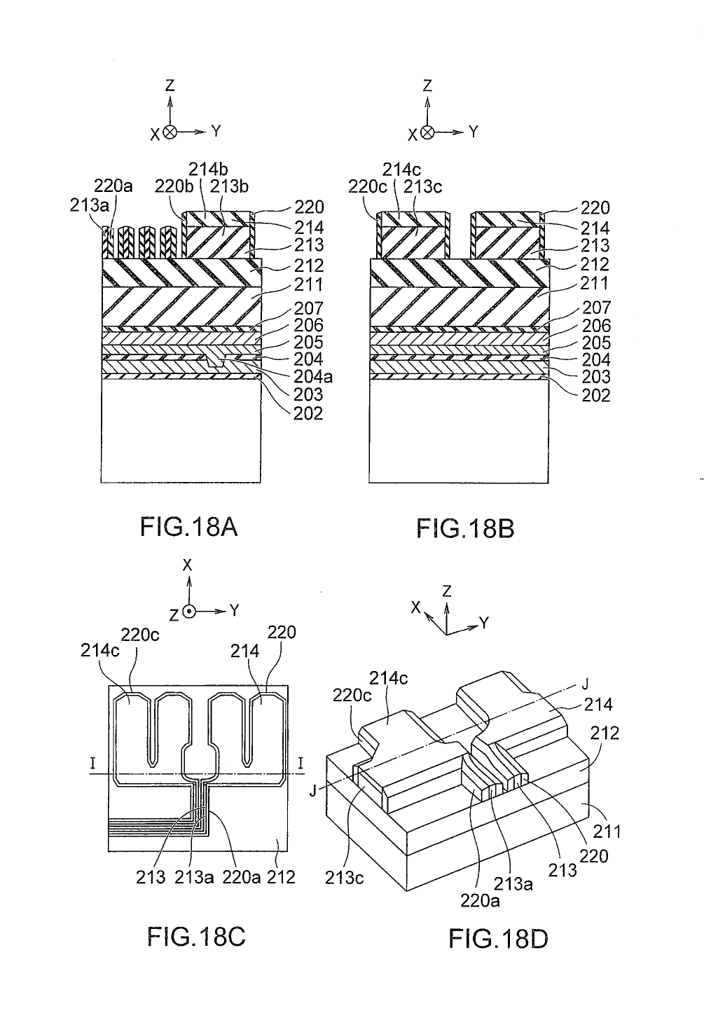

Next, as illustrated in FIGS. 18A to 18D, these remaining patterns are transferred to the first protective film 214 and the first sacrificial film 213 by etching using these patterns as a mask. As a result, the first sacrificial film 213 and the first protective film 214 are processed into third core material patterns 213a, 214a having a third width and a fourth core material pattern 213b, 214b having a fourth width larger than the third width. In addition, there is formed a plurality of second pad portions 213c, 214c connected to third core material patterns 213a, 214a. The third width is, for example, the feature size “F”.

At this time, the etching rates of the first protective film 214 and the first sacrificial film 213 are affected by the loading effect, similarly to the first embodiment.

Next, as illustrated in FIGS. 18A to 18D, a third sidewall material 220 is formed on the entire surface of the semiconductor substrate 201 by ALD. Thereafter, the third sidewall material 220 is subjected to spacer processing by RIE.

As a result, fifth sidewall patterns 220a, sixth sidewall patterns 220b and third pad sidewall patterns 220c are formed on side surfaces of the third core material patterns 213a, 214a, the fourth core material patterns 213b, 214b, and the second pad portions 213c, 214c, respectively. The first protective film 214 in the third core material patterns 213a, 214a is completely removed by the end of this process. The thickness of the third sidewall material 220 is set to, for example, the feature size “F”.

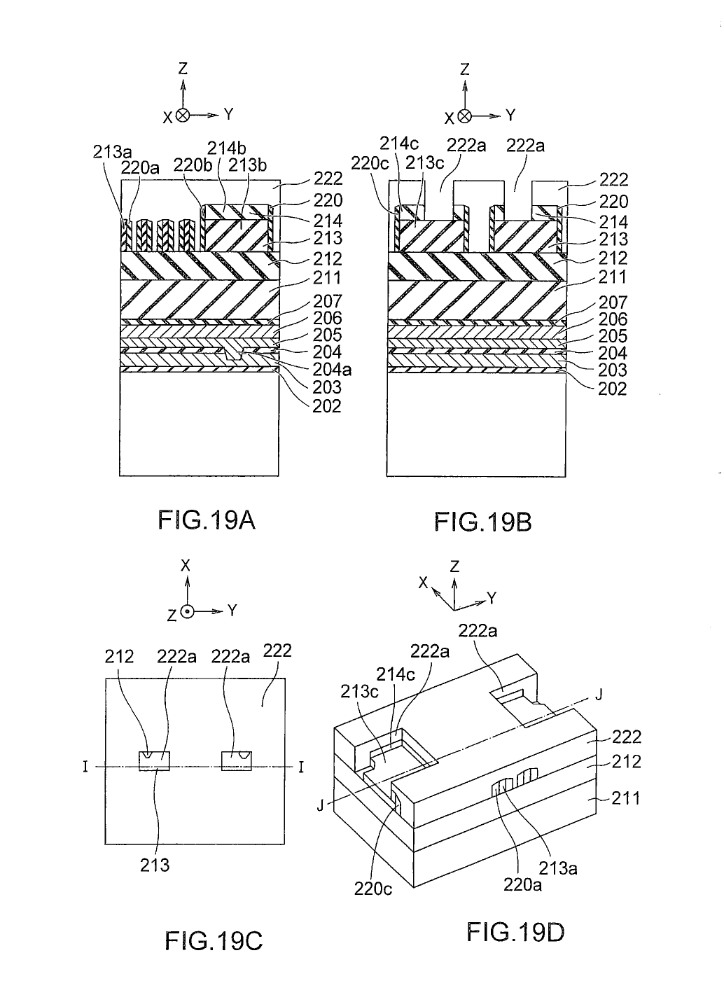

Next, as illustrated in FIGS. 19A to 19D, a resist film 222 is formed on the entire surface of the semiconductor substrate 201. Two resist openings 222a are then formed on the second pad portions 213c, 214c and the third pad sidewall patterns 220c by lithography.

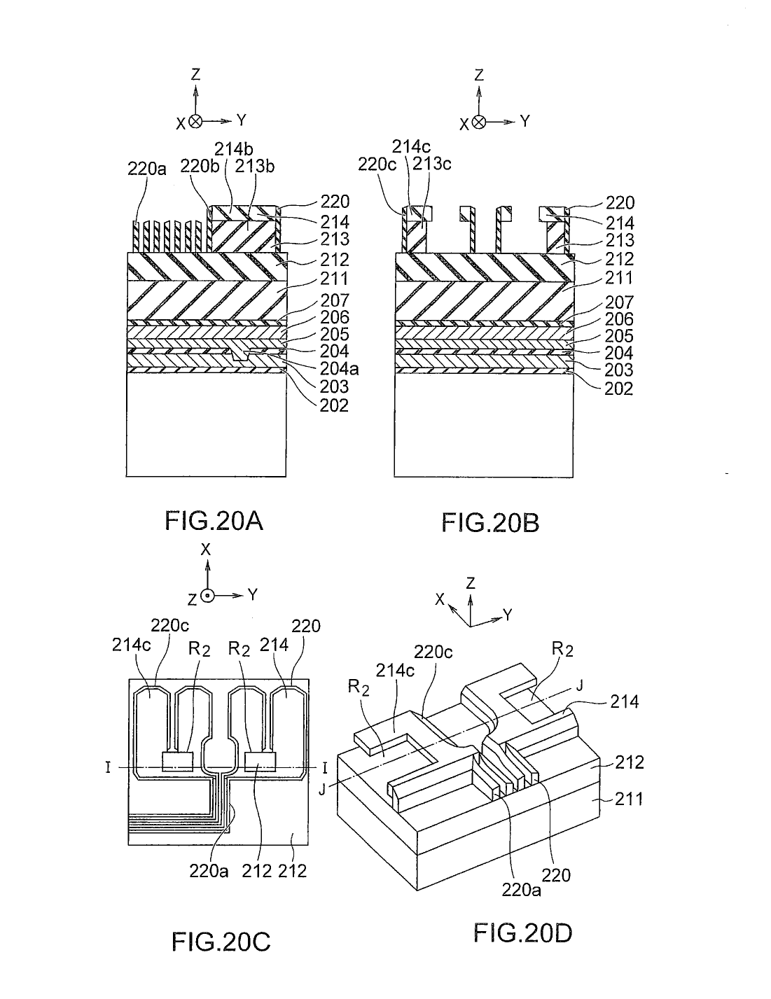

Next, the second pad portions 213c, 214c and the third pad sidewall patterns 220c in the resist openings 222a are etched by wet etching and RIE. As a result, the third pad sidewall patterns 220c are loop-cut to be divided into four parts (see FIGS. 20A to 20D).

Next, as illustrated in FIGS. 20A to 20D, the resist film 222 and the third sacrificial film 213 are selectively removed by isotropic etching such as ashing.

At this time, the first sacrificial film 213 in the third core material patterns 213a is removed since it is not covered with the first protective film 214. On the other hand, the first sacrificial film 213 in the fourth core material pattern 213b, 214b and the second pad portions 213c, 214c remains since it is covered with the first protective film 214.

As a result, the third core material patterns 213a are removed, whereas the fourth core material pattern 213b, 214b, the fifth sidewall patterns 220a, and the sixth sidewall patterns 220b remain in the process of FIGS. 20A to 20D. In addition, the second pad portions 213c, 214c and the third pad sidewall patterns 220c also remain.

The first sacrificial film 213 in the second pad portions 213c, 214c is etched by the action of the isotropic etching in the vicinity of regions R₂. As a result, the first sacrificial film 213 in the second pad portions 213c, 214c is divided in the vicinity of the regions R₂. This isotropic etching is continued until the division of the first sacrificial film 213 in the second pad portions 213c, 214c is completed.

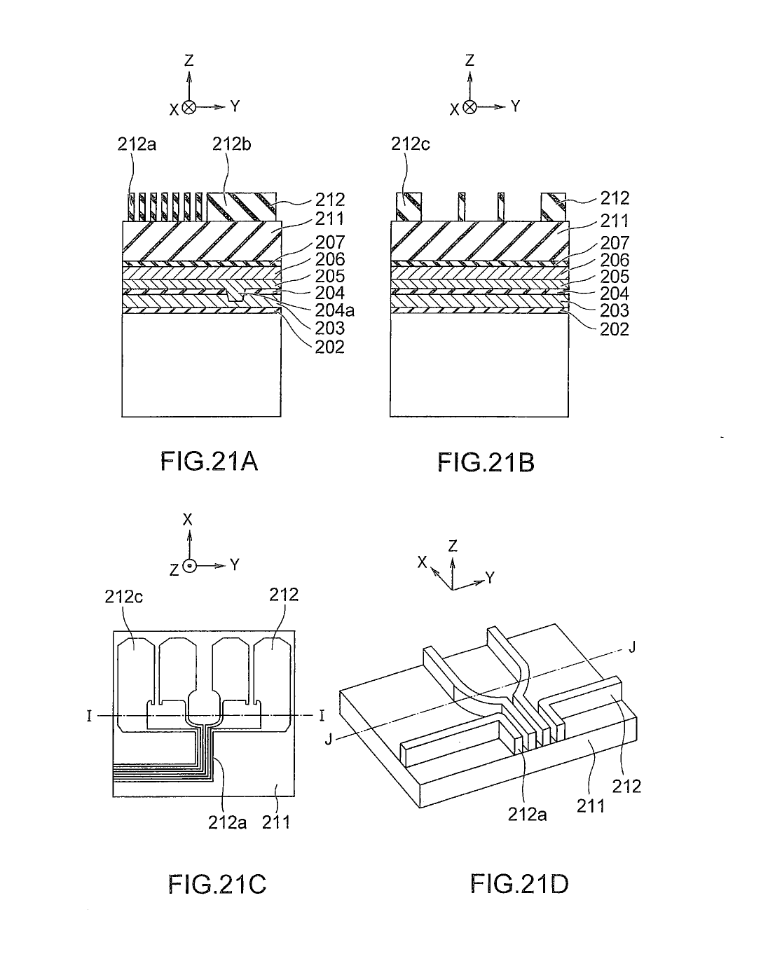

Next, as illustrated in FIGS. 21A to 21D, these remaining patterns are transferred to the second hard mask layer 212 by etching using these patterns as a mask.

As a result, the second hard mask layer 212 is processed into first mask patterns 212a having a fifth width and a second mask pattern 212b having a sixth width larger than the fifth width. In addition, there are formed pad portions 212c connected to the first mask patterns 212a. The fifth width is, for example, the feature size “F”.

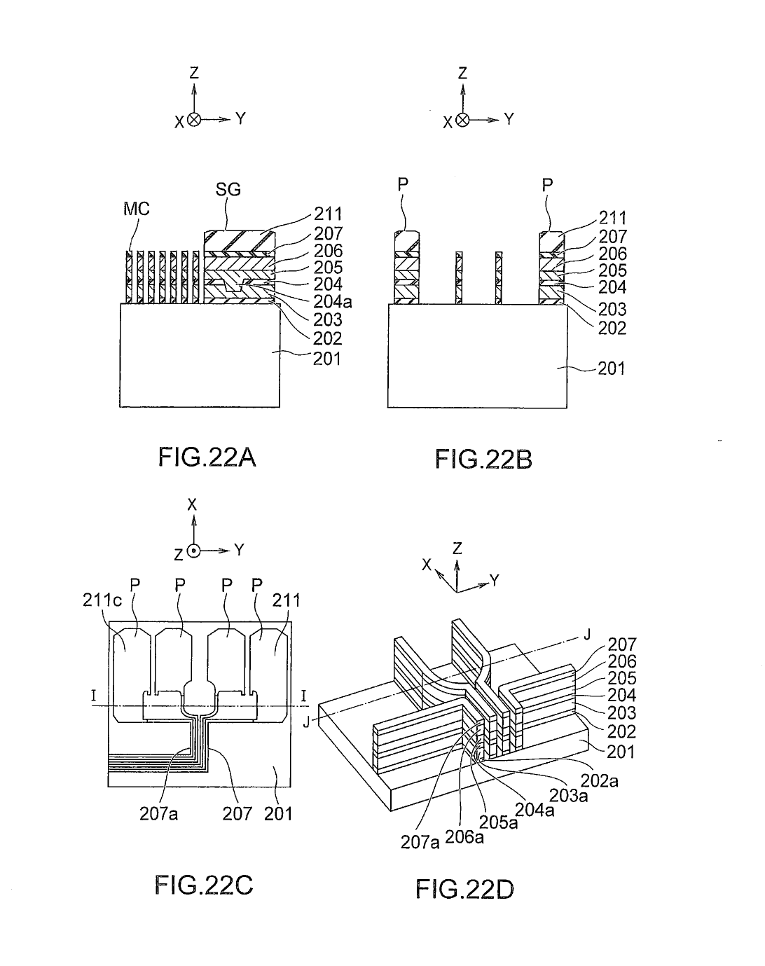

Next, as illustrated in FIGS. 22A to 22D, these patterns are transferred to the first hard mask layer 211 and further to the cap layer 207, the second floating gate material 206, the first control gate material 205, the intergate dielectric film 204, the floating gate material 203, and the gate dielectric film 202 by etching using these patterns as a mask.

As a result, there are formed cell transistors MC having a fifth width, a select transistor SG having a sixth width larger than the fifth width, and pad portions P connected to the cell transistors MC (word line). As illustrated in FIGS. 22A to 22D, each word line is provided with one pad portion P on the edge of each word line, and a contact plug is to be formed on this pad portion P.

### Effects of Second Embodiment

Hereinafter, a description will be given of effects of the second embodiment.

According to the present embodiment, a thin pattern for a cell transistor (hereinafter described as “MC”) and a thick pattern for a select transistor (hereinafter described as “SG”) or a pad portion can be formed by only three lithography processes shown in FIGS. 13A to 13D, FIGS. 16A to 16D, and FIGS. 19A to 19D.

In a case where the gate processing of the NAND memory is performed by using conventional quadruple sidewall pattern transfer, a boundary line of a resist film has to be set between a region in which MCs are to be formed and a region in which an SG is to be formed when lithography processes for the MCs and the SG are carried out. The problem at this time is that requirements for the alignment accuracy of the boundary line become more stringent with a decrease in distance between these regions.

In addition, the spacing between the MCs and the SG in the NAND memory is desirably set so as to be the same as the spacing between the MCs. If the spacing between the MCs is set to a fine pitch in a case where such settings are adopted, the spacing between the MCs and the SG is also fine-pitched, thus causing the requirements for the alignment accuracy of the boundary line to be even more stringent.

On the other hand, according to the present embodiment, since such a process of setting the boundary line is unnecessary, the present embodiment can eliminate the need for sophisticated alignment control. In addition, since the present embodiment eliminates such a process as described above, it is easy to set the spacing between the MCs and the SG to the same pitch as the spacing between the MCs.

In addition, according to the present embodiment, the pad portions to be used to dispose the contact plugs on the word lines can be formed by such a simple process as described above. For example, according to the present embodiment, since the isotropic etching shown in FIGS. 17A to 17D and FIGS. 20A to 20D can be automatically stopped at a foundation layer (the first protective film 214 or the second hard mask layer 212), it is possible to perform the etching process of the pad portions without having to use any sophisticated lithography technique.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
sequentially forming a workpiece film, a first sacrificial film, a first protective film, a second sacrificial film and a second protective film on a substrate;
processing the second protective film and the second sacrificial film to form first core material patterns having a first width and a second core material pattern having a second width larger than the first width;
forming first and second sidewall patterns formed of a first sidewall material on side surfaces of the first and second core material patterns, respectively;
forming third and fourth sidewall patterns formed of a second sidewall material on the side surfaces of the first and second core material patterns via the first and second sidewall patterns, respectively;
removing the first core material patterns and the first sidewall patterns so that the second core material pattern and the second, third and fourth sidewall patterns remain;
processing the first protective film and the first sacrificial film by transferring the second core material pattern and the second, third and fourth sidewall patterns by etching to form third core material patterns having a third width and a fourth core material pattern having a fourth width larger than the third width;
forming fifth and sixth sidewall patterns formed of a third sidewall material on side surfaces of the third and fourth core material patterns, respectively;
removing the third core material patterns so that the fourth core material pattern and the fifth and sixth sidewall patterns remain; and
processing the workpiece film by transferring the fourth core material pattern and the fifth and sixth sidewall patterns by etching.

2. The method of claim 1, wherein the second protective film in the first core material patterns is removed so that the second protective film in the second core material pattern remains by using a loading effect, between a start of forming the first and second core material patterns and an end of forming the third and fourth sidewall patterns.

3. The method of claim 1, wherein the first protective film in the third core material patterns is removed so that the first protective film in the fourth core material pattern remains by using a loading effect, between a start of forming the third and fourth core material patterns and an end of forming the fifth and sixth sidewall patterns.

4. The method of claim 1, wherein at least one of the first sacrificial film, the second sacrificial film and the first sidewall material is a carbon-containing film.

5. The method of claim 1, wherein the second sidewall material is formed of a material different from materials of the second sacrificial film and the first sidewall material.

6. The method of claim 1, wherein the third sidewall material is formed of a material different from a material of the first sacrificial film.

7. The method of claim 1, wherein the processing of the workpiece film comprises processing a hard mask layer between the workpiece film and the first sacrificial film by using the fourth core material pattern and the fifth and sixth sidewall patterns as a mask, and processing the workpiece film by using the hard mask layer as a mask.

8. The method of claim 1, wherein the first and second core material patterns are respectively formed by using, as a mask, first and second resist patterns formed by lithography and slimming.

9. The method of claim 1, wherein the workpiece film comprises a floating gate material formed on the substrate.

10. The method of claim 9, wherein the second protective film and the second sacrificial film are processed into the first and second core material patterns and a first ladder portion connecting the first core material patterns to each other.

11. The method of claim 10, wherein the first core material patterns and the first sidewall patterns are removed so that the first ladder portion remains.

12. The method of claim 11, wherein the first protective film and the first sacrificial film are processed into the third and fourth core material patterns and a second ladder portion connecting the third core material patterns to each other.

13. The method of claim 12, wherein the third core material patterns are removed so that the second ladder portion remains.

14. The method of claim 9, wherein the processing of the workpiece film forms isolation trenches on the substrate.

15. The method of claim 1, wherein the workpiece film comprises a floating gate material and a control gate material formed on the substrate.

16. The method of claim 15, wherein the second protective film and the second sacrificial film are processed into the first and second core material patterns and first pad portions connected to the first core material patterns.

17. The method of claim 16, further comprising dividing, by etching, first and second pad sidewall patterns which are respectively formed of the first and second sidewall materials and are formed on side surfaces of the first pad portions, after the third and fourth sidewall patterns are formed.

18. The method of claim 17, wherein the first protective film and the first sacrificial film are processed into the third and fourth core material patterns and second pad portions connected to the third core material patterns.

19. The method of claim 18, further comprising dividing, by etching, third pad sidewall patterns which are formed of the third sidewall material and are formed on side surfaces of the second pad portions, after the fifth and sixth sidewall patterns are formed.

20. The method of claim 15, wherein the processing of the workpiece film forms gate structures of cell and select transistors.
